(19) United States
(12) Patent Application Publication
(10) Pub. No.: US 2023/0123305 A1
(43) Pub. Date: Apr. 20, 2023

(54) AMPLIFYING CIRCUIT

(71) Applicant: Realtek Semiconductor Corp., HsinChu (TW)

(72) Inventors: Yang Chang, HsinChu (TW); Kuan-Yu Shih, HsinChu (TW); Chia-Jun Chang, HsinChu (TW)

(73) Assignee: Realtek Semiconductor Corp., HsinChu (TW)

(21) Appl. No.: 17/965,732

(22) Filed: Oct. 13, 2022

(30) Foreign Application Priority Data
Oct. 18, 2021 (TW) 110138558

(51) Int. Cl. H03F 1/22; H03F 3/45

(52) U.S. Cl. CPC H03F 1/223; H03F 3/45179; H03F 2200/294

(57) ABSTRACT

An amplifying circuit comprises: a plurality of first transistors; a second transistor coupled in series with the first transistor; and a compensation capacitor group comprising a plurality of compensation capacitors and a plurality of switches. When the amplifying circuit operates in a first gain mode, a first number of first transistors are turned on and a second number of compensation capacitors are coupled between the first terminal and the second terminal of the first transistor. When the amplifying circuit operates in a second gain mode, a third number of first transistors are turned on and a fourth number of compensation capacitors are coupled between the first terminal and the second terminal of the first transistor. The first number is larger than the third number, and the second number is larger than the fourth number.

### BACKGROUND OF THE INVENTION

### 1. Field of the Invention

The present invention relates to an amplifying circuit, and particularly relates to an amplifying circuit which can reduce parasitic capacitance effect.

### 2. Description of the Prior Art

A cascode Low Noise Amplifier (LNA) in the prior art can provide the required gain. However, parasitic capacitance effect may occur between the transistors, which increases the noise figure of the cascode LNA. Parasitic capacitance may also cause other problems. For example, the parasitic capacitance has an unstable capacitance value, so it may also make the cascode LNA unstable.

The conventional cascode LNA usually has no mechanism for reducing the parasitic capacitance effect. Some cascode LNAs use components such as inductors to cancel out parasitic capacitance. However, these components may cause leakage current problems.

Therefore, a new mechanism is needed to reduce the parasitic capacitance effect.

### SUMMARY OF THE INVENTION

Therefore, one objective of the present invention is to provide an amplifying circuit, which can reduce parasitic capacitance effect.

One embodiment of the present invention discloses an amplifying circuit, comprising: a first transistor; a second transistor, coupled to the first transistor in series; a plurality of switches; and a plurality of compensation capacitors, selectively coupled to a first terminal and a second terminal of the first transistor, wherein the first terminal and the second terminal are not control terminals. Each of the compensation transistors is coupled to a corresponding one of the switches in series. The compensation capacitors are coupled in parallel.

Another embodiment of the present invention discloses an amplifying circuit, comprising: a plurality of first transistors; a second transistor, coupled to the first transistors in series; and a compensation capacitor group, comprising a plurality of compensation capacitors and a plurality of switches. Each of the compensation capacitors is coupled to a corresponding one of the switches in series. The compensation capacitors are coupled in parallel. When the amplifying circuit operates in a first gain mode, a first number of the first transistors are turned on and a second number of the compensation capacitors are coupled between a first terminal and a second terminal of the first transistors. When the amplifying circuit operates in a second gain mode, a third number of the first transistors are turned on and a fourth number of the compensation capacitors are coupled between the first terminal and the second terminal of the first transistors. The first number is larger than the third number, and the second number is larger than the fourth number.

In view of above-mentioned embodiments, the negative capacitance can be used to cancel out the parasitic capacitance in the amplifying circuit, thereby improving the problem of parasitic capacitance effect in the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram illustrating an amplifying circuit according to one embodiment of the present invention.

FIG. 2 is an equivalent circuit diagram for the embodiment illustrated in FIG. 1.

FIG. 3 and FIG. 4 are signal receiving circuits which apply the amplifying circuit in FIG. 1, according to different embodiments of the present invention.

FIG. 5 is a circuit diagram of the control circuit illustrated in FIG. 3 and FIG. 4, according to one embodiment of the present invention.

FIG. 6 is a detail circuit diagram of an adjustable current source, according to one embodiment of the present invention.

### DETAILED DESCRIPTION

Several embodiments are provided in following descriptions to explain the concept of the present invention. Additionally, the term “first”, “second”, “third” in following descriptions are only for the purpose of distinguishing different one elements, and do not mean the sequence of the elements. For example, a first device and a second device only mean these devices can have the same structure but are different devices.

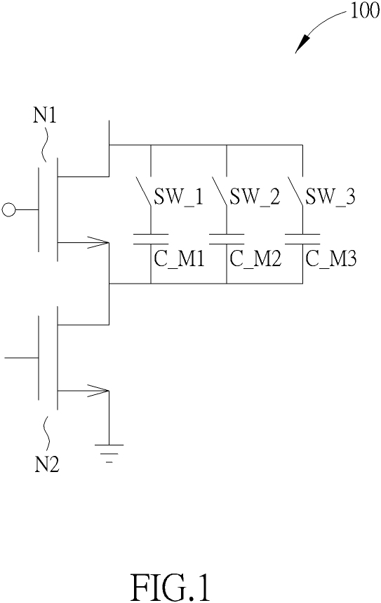

FIG. 1 is a circuit diagram illustrating an amplifying circuit according to one embodiment of the present invention, which can be a cascode LNA. As shown in FIG. 1, the amplifying circuit 100 comprises an NMOS (N type Metal-Oxide-Semiconductor Field-Effect Transistor) N1, an NMOS N2, a plurality of compensation capacitors C_M1, C_M2, C_M3 and a plurality of switches SW_1, SW_2, SW_3. The compensation capacitors C_M1, C_M2, and C_M3 are respectively coupled with a corresponding switch in series and in parallel with each other. The NMOS N2 is coupled with the NMOS N1 in series. Specifically, the drain of the NMOS N2 is coupled to the source of NMOS N1. The compensation capacitors C_M1, C_M2, C_M3 and the switches SW_1, SW_2, SW_3 are selectively coupled between the drain and the source of the NMOS N1 according to whether the switches SW_1, SW_2, and SW_3 are conducted. In one embodiment, the NMOS N1 is a common gate amplifier, and the NMOS N2 is a common source amplifier. Also, the compensation capacitors C_M1, C_M2, C_M3 and switches SW_1, SW_2, SW_3 are located between the drain and the source of the NMOS N1. Compensation capacitors C_M1, C_M2, C_M3 and switches SW_1, SW_2, SW_3 can be called a compensation capacitor group. The compensation capacitor group can comprise multiple capacitors and multiple switches as shown in FIG. 1, or it can comprise only a single capacitor and a single switch. By controlling at least one of the switches SW_1, SW_2, and SW_3 to be conducted, one of the compensation capacitors C_M1, C_M2, C_M3 can form the required compensation capacitor, or at least two of the compensation capacitors C_M1, C_M2, C_M3 can be coupled in parallel to form a required compensation capacitor. The advantage of the compensation capacitor group comprising multiple capacitors and multiple switches is that due to the complexity of modern manufacturing processes, it is difficult to accurately estimate the parasitic capacitance effect caused by process variations. Therefore, a single compensation capacitor can be used or multiple compensation capacitors can be coupled in parallel for compensating the parasitic capacitance effect. By this way, the compensation capacitor group can make the best compensation corresponding to the process variation.

The common gate amplifier is one of the constructions of an amplifier, which can be used in but not limited to current buffers or voltage amplifiers. For more detail, under this architecture, the source of the transistor serves as the signal input terminal, the drain serves as the signal output terminal, and the gate serves as the common terminal. In the embodiment in FIG. 1, the NMOS N1 is a common gate amplifier. A common source amplifier is another construction of an amplifier, which can be used in, but not limited to, a voltage amplifier or a transconductance amplifier. In the embodiment in FIG. 1, the signal received by the NMOS N2 enters its gate and leaves from its drain, so the NMOS N2 is a common source amplifier. Please also note that in the embodiment in FIG. 1, the signals or voltages received at each terminal of the NMOS N1 and NMOS N2 are not marked. In following embodiments, the example applying the amplifying circuit 100, and the signals or the voltages received at each terminal of the NMOS N1 and NMOS N2, will be described.

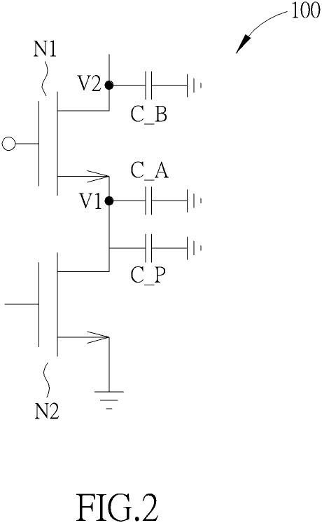

FIG. 2 is an equivalent circuit diagram for the embodiment illustrated in FIG. 1. As shown in FIG. 2, a parasitic capacitor C_P may exist between the NMOS N1 and the NMOS N2 due to parasitic capacitance effects. The compensation capacitor group in FIG. 1 can form the equivalent capacitor C_A and the equivalent capacitor C_B illustrated in FIG. 2. If the voltage gain of the NMOS N1 is A and the capacitance value of the compensation capacitor C is CV,

$$\frac{V 2}{V 1}$$

=A, V2 and V1 are the drain voltage and source voltage of NMOS N1 respectively. Then the capacitance value of the equivalent capacitor C_A is(1-A)CV , and the capacitance value of the equivalent capacitor C_B is (1-A⁻¹)CV. If A is larger than 1, the equivalent capacitor C_A forms a negative capacitance effect. Therefore, the equivalent capacitor C_A can be cancelled out with the parasitic capacitor C_P to reduce circuit problems caused by the parasitic capacitor in the prior art.

The NMOS N1 and the NMOS N2 in FIG. 1 can be replaced by other transistors. For example, they can be replaced by PMOS (P type Metal-Oxide-Semiconductor Field-Effect Transistor). Therefore, the amplifying circuit 100 shown in FIG. 1 can be simplified as: an amplifying circuit comprising: a first transistor (for example, NMOS N1); a second transistor (for example, NMOS N2) coupled to the first transistor in series; a plurality of compensation capacitors and a plurality of switches (such as compensation capacitors C_M1, C_M2, C_M3 and switches SW_1, SW_2, SW_3). The compensation capacitor is selectively coupled to a first terminal and a second terminal of the first transistor, wherein the first terminal and the second terminal are not control terminals. For example, the first terminal and the second terminal are drain and source respectively. Each compensation capacitor is coupled to a corresponding one of the switches in series . Also, the compensation capacitors are coupled in parallel.

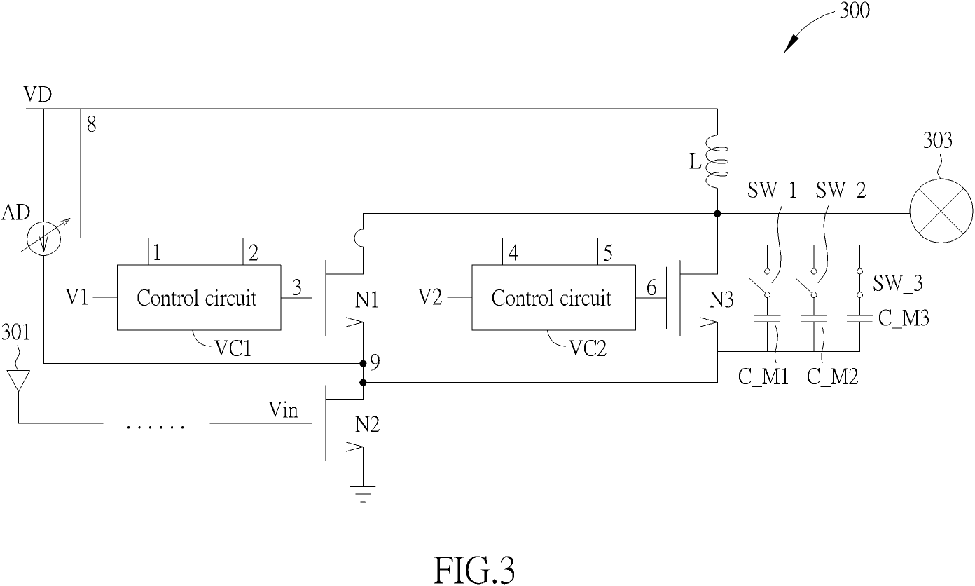

The amplifying circuit shown in FIG. 1 can be used in different circuits. In one embodiment, it is applied to a signal receiving circuit. FIG. 3 and FIG. 4 are signal receiving circuits which apply the amplifying circuit in FIG. 1, according to different embodiments of the present invention. Please note, in following descriptions, only the components that are more relevant to the present invention are shown in the embodiments in FIG. 3 and FIG. 4. However, as known by persons skilled in the art, the signal receiving circuit may have other additional components corresponding to its operation, such as resistors, capacitors, inductors, matching circuits, and bias circuits. Such changes should be comprised in the scope of the present invention. Moreover, the amplifying circuit provided by the present invention is not limited to be used in the signal receiving circuit shown in FIG. 3.

As shown in FIG. 3, the signal receiving circuit 300 comprises an antenna 301, a mixer 303, control circuits VC1, VC2, an amplifying circuit, and a compensation capacitor group. The amplifying circuit comprises the NMOSs N1, N2 shown in FIG. 1, and further comprises an NMOS N3, and the compensation capacitor group comprises a plurality of compensation capacitors C_M1, C_M2, C_M3 coupled in parallel as shown in the embodiment of FIG. 1. NMOSs N1 and N3 are common gate amplifiers, and the NMOS N2 is a common source amplifier. The drains of the NMOSs N1 and N3 are coupled to an inductor L, which is coupled to a first predetermined voltage VD, and the gates thereof respectively receive the output of the control circuits VC1 and VC2. In other words, the control circuits VC1 and VC2 are used to control turning on/turning off of the NMOSs N1 and N3. The gate of the NMOS N2 receives an input voltage Vin, which is generated according to an input signal received by the antenna 301, and the source of the NMOS N2 is coupled to a ground voltage level. In addition, in the embodiment in FIG. 3, the compensation capacitor group comprises three compensation capacitors C_M1, C_M2, C_M3 coupled in parallel, but it is not limited to comprise three compensation capacitors. The first predetermined voltage VD can be provided by another voltage supply source. For example, in one embodiment, the first predetermined voltage VD is provided by a low dropout regulator (LDO) .

The amplifying circuit in FIG. 3 can operate in different gain modes, and the number of compensation capacitors coupled to the NMOS N1 and N3 is proportional to the gain provided by the amplifying circuit. In other words, the more common gate amplifiers in the amplifying circuit are turned on, the higher the gain, and the larger the number of compensation capacitors coupled to the NMOS N1 and N3 in parallel. On the contrary, the fewer common gate amplifiers in the amplifying circuit are turned on, the lower the gain, and the smaller the number of compensation capacitors coupled to the NMOS N1 and N3 in parallel. The advantage of such mechanism is that the more common gate amplifiers in the amplifying circuit are turned on, the more obvious the parasitic capacitance effect will be. Therefore, more compensation capacitances are coupled in parallel to generate a larger compensation capacitance to cancel out the parasitic capacitance.

In the embodiment of FIG. 3, the amplifying circuit in the signal receiving circuit 300 operates in a low gain mode, that is, one of the NMOS N1 and N3 is turned on and the other is turned off, and therefore has a lower gain. In this example, only one compensation capacitor C_M3 is coupled between the drain and source of the NMOS N3, and the other compensation capacitors C_M1 and C_M2 are not coupled between the drain and source of the NMOS N3. In brief, the switches SW_1 and SW_2 corresponding to the compensation capacitors C_M1 and C_M2 are not conducted, while the switch SW_3 corresponding to the compensation capacitor C_M3 is conducted.

Please refer to FIG. 3 again. In one embodiment, the signal receiving circuit 300 further comprises an adjustable current source AD. As mentioned above, when the amplifying circuit in the signal receiving circuit 300 operates in the low gain mode, one of the NMOS N1 and N3 is turned on and the other is turned off. In such case, the adjustable current source AD is turned on to form a current sink path, so that the current flows from the terminal 8 to the terminal 9 through the current sink path, and the current flowing through the inductor L is reduced. Thereby the gain of the turned on NMOS N1 or NMOS N3 can be further reduced, that is, the gain of the amplifier 300 can be further decreased. In one embodiment, the adjustable current source AD can drain current stepwise, that is, drain a smaller current and slightly reduce the gain of the turned on NMOS N1 or NMOS N3, or drain a larger current, such that greatly reduce the gain of the turned on NMOS N1 or NMOS N3. The detailed structure of the adjustable current source AD will be explained in the following descriptions.

In the embodiment shown in FIG. 4, the amplifying circuit in the signal receiving circuit 300 operates in a high gain mode, that is, the NMOS N1 and N3 are both turned on, so the amplifying circuit has a higher gain. In such example, the compensation capacitors C_M2 and C_M3 are both coupled between the drain and source of the NMOS N3, and the compensation capacitor C_M1 is not coupled between the drain and the source of the NMOS N3. Briefly, the switch SW_1 corresponding to the compensation capacitor C_M1 is turned off, while the switches SW_2 and SW_3 corresponding to the compensation capacitor C_M2 and C_M3 are turned on. As mentioned above, the signal receiving circuit 300 may further comprise an adjustable current source AD. The adjustable current source AD can be in a non-conducted state in the high gain mode, that is, no current drain path is formed.

The NMOS in the embodiments of FIGS. 3 and 4 can be replaced by other transistors, and the number of common gate amplifiers is not limited to two. Also, the number of compensation capacitors is not limited to three. Therefore, the amplifying circuit shown in FIGS. 3 and 4 can be simplified as: an amplifying circuit comprising: a plurality of first transistors (such as NMOSs N1, N3); a second transistor (such as NMOS N2), coupled to the first transistors in series; and a compensation capacitor group, comprising a plurality of compensation capacitors and a plurality of switches (for example, compensation capacitors C_M1, C_M2, C_M3 and switches SW_1, SW_2, SW_3) . Each of the compensation capacitors is coupled to a corresponding one of the switches in series, wherein the compensation capacitors are coupled in parallel. When the amplifying circuit operates in a first gain mode (such as the aforementioned high gain mode), a first number of first transistors are turned on (such as NMOSs N1, N3) and a second number of compensation capacitors (such as compensation capacitors C_M2, C_M3) are coupled between a first terminal and a second terminal of the first transistors. When the amplifying circuit operates in a second gain mode (such as the aforementioned low gain mode), a third number of first transistors (such as NMOS N1) is turned on and a fourth number of compensation capacitors (such as the compensation capacitor C_M1) is coupled between the first terminal and the second terminal of the first transistors. When the second number or the third number is greater than or equal to two, the compensation capacitors are coupled in parallel with each other. The first number is larger than the third number, and the second number is larger than the fourth number. In one embodiment, the first number is two, the third number is one, the second number is two, and the fourth number is one.

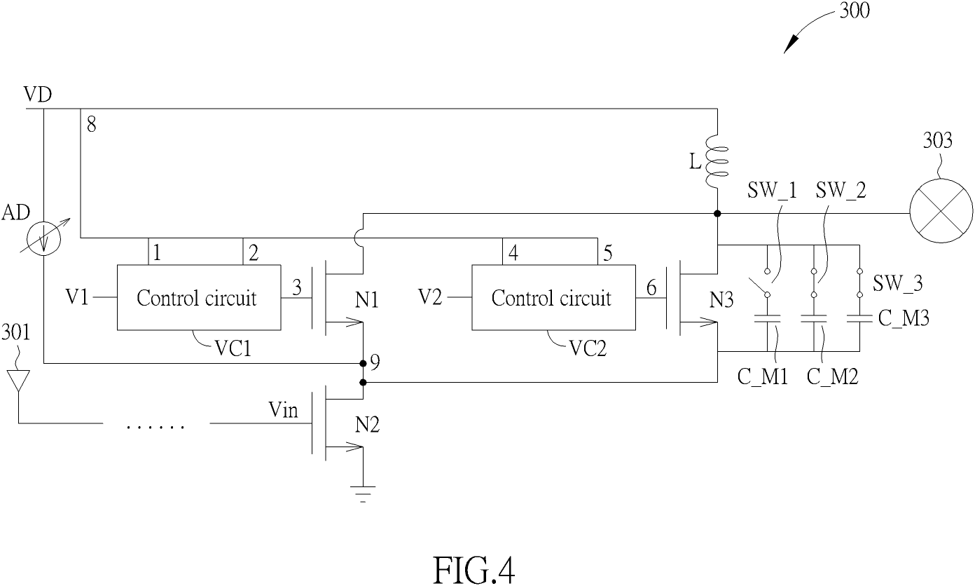

The control circuits VC1 and VC2 in FIGS. 3 and 4 can be implemented in a variety of ways. FIG. 5 is a circuit diagram of the control circuit illustrated in FIG. 3 and FIG. 4, according to one embodiment of the present invention. As shown in FIG. 5, the control circuit VC1 comprises two inverters IV1 and IV2. The inverter IV1 is configured to receive a voltage V1. The inverters IV1 and IV2 are respectively coupled to the terminals 1 and 2 in FIGS. 3 and 4, and the output of the inverter IV2 is coupled to the terminal 3 in FIGS. 3 and 4. When the voltage V1 is at the high logic level 1, the terminal 3 is conducted to the terminal 8, therefore the NMOS N1 receives the first predetermined voltage VD and is turned on. When the voltage V1 is at a low logic level of 0, the terminal 3 is conducted to the ground voltage level so that the NMOS N1 is turned off. Therefore, by controlling the voltage V1, the turn on, turn off of the NMOS N1 can be controlled. However, please note that the amplifying circuit provided by the present invention is not limited to being controlled by the control circuit shown in FIG. 5. In the embodiment of FIG. 5, only the control circuit VC1 is used for description. However, the control circuit VC2 may also have the same structure. Therefore, the control circuit VC2 may also have inverters IV1 and IV2 as shown in FIG. 5. The inverters IV1 and IV2 of the control circuit VC2 are respectively coupled to the terminals 4 and 5 in FIGS. 3 and 4. The output of the inverter IV2 of the control circuit VC2 is coupled to the terminal 6 in FIGS. 3 and 4. When the voltage V2 is at the high logic level 1, the terminal 6 and the terminal 8 are conducted, so the NMOS N3 receives the first predetermined voltage VD and is turned on. When the voltage V2 is at a low logic level of 0, the terminal 6 is conducted to the ground voltage level so that the NMOS N3 is turned off. Therefore, by controlling the voltage V2, the turn on, turn off of the NMOS N3 can be controlled.

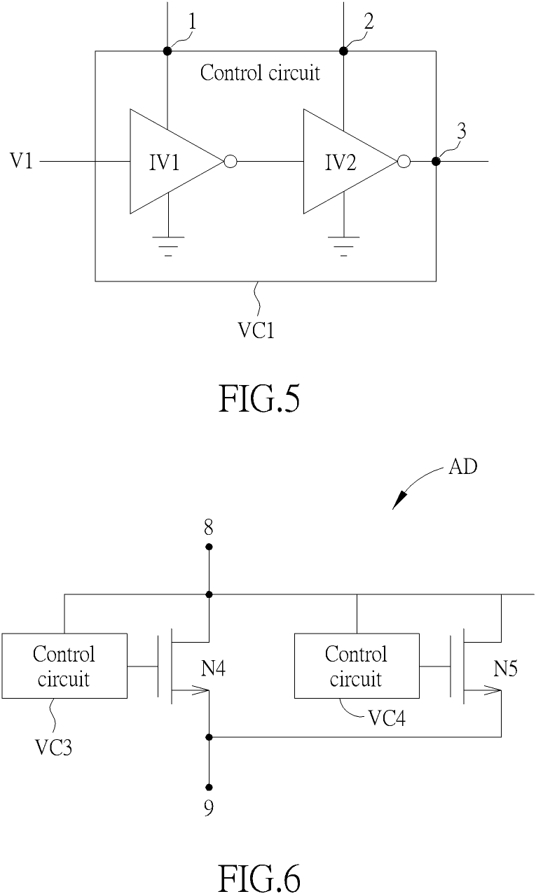

FIG. 6 is a detail circuit diagram of an adjustable current source, according to one embodiment of the present invention. As shown in FIG. 6, the adjustable current source AD comprises control circuits VC3, VC4, and NMOSs N4, N5. The control circuit VC3, VC4 can receive the control voltage to control the NMOSs N4, N5. The NMOSs N4 and N5 are coupled between the terminal 8 and the terminal 9 described in FIGS. 3 and 4, and can be replaced by PMOS. When operating in the low gain mode described in FIG. 3, at least one of the NMOSs N4 and N5 is turned on to generate a current drain path. When only one of NMOSs N4 and N5 is turned on, the adjustable current source AD drains less current and slightly reduces the gain of the amplifying circuit. When both NMOSs N4 and N5 are turned on, the adjustable current source AD drains a larger current and greatly reduce the gain of the amplifying circuit.

In view of above-mentioned embodiments, the negative capacitance can be used to cancel out the parasitic capacitance in the amplifying circuit, thereby improving the problem of parasitic capacitance effect in the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplifying circuit, comprising:
a first transistor;
a second transistor, coupled to the first transistor in series;
a plurality of switches; and
a plurality of compensation capacitors, selectively coupled to a first terminal and a second terminal of the first transistor, wherein the first terminal and the second terminal are not control terminals;
wherein each of the compensation transistors is coupled to a corresponding one of the switches in series;
wherein the compensation capacitors are coupled in parallel.

2. The amplifying circuit of claim 1, wherein the first transistor is a common gate amplifier, and the second transistor is a common source amplifier.

3. The amplifying circuit of claim 1, wherein the first transistor and the second transistor are NMOSs, the first terminal is a drain, and the second terminal is a source.

4. The amplifying circuit of claim 3, wherein the first terminal of the first transistor receives a first predetermined voltage, wherein the second terminal of the first transistor is coupled to a drain of the second transistor, a gate of the second transistor receives an input voltage, and a source of the second transistor is coupled to a ground voltage level.

5. The amplifying circuit of claim 1, wherein the first transistor and the second transistor are PMOSs, the first terminal is a source, and the second terminal is a drain.

6. The amplifying circuit of claim 3, wherein the first terminal of the first transistor receives a first predetermined voltage, wherein the second terminal of the first transistor is coupled to a source of the second transistor, a gate of the second transistor receives an input voltage, and a drain of the second transistor is coupled to a ground voltage level.

7. The amplifying circuit of claim 1, wherein the compensation capacitors are applied for compensating parasitic capacitance between the first transistor and the second transistor.

8. An amplifying circuit, comprising:
a plurality of first transistors;
a second transistor, coupled to the first transistors in series; and
a compensation capacitor group, comprising a plurality of compensation capacitors and a plurality of switches, wherein each of the compensation transistors is coupled to a corresponding one of the switches in series, wherein the compensation capacitors are coupled in parallel;
wherein when the amplifying circuit operates in a first gain mode, a first number of the first transistors are turned on and a second number of the compensation capacitors are coupled between a first terminal and a second terminal of the first transistors;
wherein when the amplifying circuit operates in a second gain mode, a third number of the first transistors are turned on and a fourth number of the compensation capacitors are coupled between the first terminal and the second terminal of the first transistors;
wherein the first number is larger than the third number, and the second number is larger than the fourth number.

9. The amplifying circuit of claim 8, wherein the first transistors are common gate amplifiers, and the second transistor is a common source amplifier.

10. The amplifying circuit of claim 8, wherein the first transistor and the second transistor are NMOSs, the first terminal is a drain, and the second terminal is a source.

11. The amplifying circuit of claim 10, wherein the first terminals of the first transistors receive a first predetermined voltage, wherein the second terminal of the first transistor is coupled to a drain of the second transistor, a gate of the second transistor receives an input voltage, and a source of the second transistor is coupled to a ground voltage level.

12. The amplifying circuit of claim 8, wherein the first transistors and the second transistor are PMOSs, the first terminals are source, and the second terminals are drains.

13. The amplifying circuit of claim 12, wherein the first terminals of the first transistors receive a first predetermined voltage, wherein the second terminals of the first transistors are coupled to a source of the second transistor, a gate of the second transistor receives an input voltage, and a drain of the second transistor is coupled to a ground voltage level.

14. The amplifying circuit of claim 8, wherein the amplifying circuit is located in a signal receiving circuit, wherein a control terminal of the second transistor receives an input voltage, wherein the input voltage is generated according to an input signal received by the signal receiving circuit.

15. The amplifying circuit of claim 8, further comprising an adjustable current source, wherein the adjustable current source provides a current drain path to decrease a gain of the amplifying circuit when the amplifying circuit operates in the second gain mode.

16. The amplifying circuit of claim 8, wherein the compensation capacitors are applied for compensating parasitic capacitance between the first transistors and the second transistor.
